(19) United States
(12) Patent Application Publication
(10) Pub. No.: US 2017/0271443 A1
(43) Pub. Date: Sep. 21, 2017

(54) SEMICONDUCTOR DEVICE

(71) Applicant: KABUSHIKI KAISHA TOSHIBA, Tokyo (JP)

(72) Inventor: Ryoichi OHARA, Himeji Hyogo (JP)

(21) Appl. No.: 15/247,772

(22) Filed: Aug. 25, 2016

(30) Foreign Application Priority Data
Mar. 16, 2016 (JP) 2016053108

(51) Int. Cl. H01L 29/06; H01L 29/40; H01L 29/872; H01L 29/16

(52) U.S. Cl. CPC H01L 29/0634; H01L 29/1608; H01L 29/408; H01L 29/872

(57) ABSTRACT

A semiconductor device includes a silicon carbide layer having first and second surfaces. The layer includes a first conductivity type first region extending from the first surface to the second surface, a second conductivity type second region extending inwardly of the first surface and surrounding a portion of the first region, and a second conductivity type third region surrounding the second region. The third region has an impurity concentration lower than the impurity concentration of the second region. The semiconductor device includes a first electrode extending over the portion of the first region and a portion of the second region, a first insulating layer extending over the third region and partially over the second region, and a second insulating layer overlying the first insulating layer and having a first portion and a second portion thicker than the first portion overlying the boundary between the second and third regions.

### CROSS-REFERENCE TO RELATED APPLICATION

This application is based upon and claims the benefit of priority from Japanese Patent Application No. 2016-053108, filed Mar. 16, 2016, the entire contents of which are incorporated herein by reference.

### FIELD

Embodiments described herein relate generally to a semiconductor device.

### BACKGROUND

Silicon carbide is expected to be used as a material for next generation semiconductor devices. Silicon carbide has excellent physical properties such as a bandgap three times that of silicon, a breakdown electric field strength approximately ten times that of silicon, and a thermal conductivity approximately three times that of silicon. As a result, it is possible to create a semiconductor device using silicon carbide, in which power loss is low while operating at high-temperature.

In a vertical device in which an electrode is provided on a front surface and a rear surface of a semiconductor layer, a termination structure such as a reduced surface field (resurf) and a guard ring may be provided at the periphery of an element region so as to improve a breakdown voltage. When the termination structure is provided, electric field concentration at an end of the element region is mitigated, and thus occurrence of avalanche breakdown at the end of the element region is suppressed.

As described above, breakdown electric field strength of silicon carbide is approximately ten times that of silicon. Thus, using silicon carbide it is possible to increase the electric field strength on the semiconductor layer having the termination structure. When the electric field strength applied to the semiconductor layer increases, the electric field leaked to an outer side of the semiconductor layer also increases.

When packaging a semiconductor device, for example, sealing may be performed with a sealing resin such as an epoxy resin and a silicon resin. When the electric field strength leaked to the outer side of the semiconductor layer increases, insulation breakdown of the sealing resin and the like occur, and thus the reliability of the semiconductor device deteriorates.

### DESCRIPTION OF THE DRAWINGS

FIG. 1 is a schematic cross-sectional view of a semiconductor device according to a first embodiment;

FIG. 2 is a schematic plan view of the semiconductor device according to the first embodiment;

FIG. 3 is a partially enlarged schematic cross-sectional view of the semiconductor device according to the first embodiment;

FIG. 4 is a partially enlarged schematic cross-sectional view of a semiconductor device according to a second embodiment;

FIG. 5 is a schematic cross-sectional view of a semiconductor device according to a third embodiment; and

FIG. 6 is a schematic cross-sectional view of a semiconductor device according to a fourth embodiment.

### DETAILED DESCRIPTION

In general, according to one embodiment, there is provided a semiconductor device including a silicon carbide layer having a first surface and a second surface. The silicon carbide layer includes a first conductivity type first region extending from the first surface to the second surface, a second conductivity type second region extending inwardly of the first surface and surrounding a portion of the first region at the first surface, and a second conductivity type third region surrounding the second region. The third region has a second conductivity type impurity concentration lower than the second conductivity type impurity concentration of the second region. The semiconductor device further includes a first electrode extending over the portion of the first region at the first surface and a portion of the second region, a first insulating layer extending over the third region and partially over the second region, and a second insulating layer overlying the first insulating layer and having a first portion, and a second portion thicker than the first portion overlying the boundary between the second and third regions.

Hereinafter, embodiments will be described with reference to the accompanying drawings. Furthermore, in the following description, the same reference numeral will be given to the same or similar members and the like, and description thereof will be appropriately omitted.

Notations of “n⁺”, “n”, “n⁻”, “P⁺⁺”, “p⁺”, “p”, and “p⁻” represent relative magnitudes of impurity concentrations of semiconductor layers of respective conductivity types. That is, “n⁺” represents that an n-type impurity concentration is relatively higher in comparison to “n”, and “n⁻” represents that the n-type impurity concentration is relatively lower in comparison to “n”. Furthermore, “P⁺⁺” represents that a p-type impurity concentration is relatively higher in comparison to “p⁺”, “p⁺” represents that the p-type impurity concentration is relatively higher in comparison to “p”, and “p⁻” represents that the p-type impurity concentration is relatively lower in comparison to “p”. Furthermore, “n⁺-type” and “n⁻-type” may be simply described as “n-type”, and “P⁺⁺-type”, “p⁺-type” and “p⁻-type” may be simply described as “p-type”.

For example, the impurity concentration can be measured by secondary ion mass spectrometry (SIMS). In addition, for example, the relative magnitude of the impurity concentration can be determined from a magnitude of the carrier concentration that is obtained by scanning capacitance microscopy (SCM). In addition, for example, a distance such as a depth of an impurity region can be obtained by the SIMS. In addition, for example, the depth of the impurity region can be obtained from a composite image of an SCM image and an atomic force microscope (AFM) image.

### First Embodiment

A semiconductor device according to this embodiment includes a silicon carbide layer having a first surface and a second surface. The silicon carbide layer has a first conductivity type first region extending from the first surface to the second surface, a second conductivity type second region extending inwardly of the first surface and surrounding a portion of the first region at the first surface, and a second conductivity type third region surrounding the second region. The third region has a second conductivity type impurity concentration lower than the second conductivity type impurity concentration of the second region. A first electrode extends over the portion of the first region at the first surface and a portion of the second region. A first insulating layer extends over the third region and partially over the second region, and a second insulating layer having a first thickness portion, and a second thickness portion thicker than the first portion, overlies the first insulating layer and the boundary between the second and third regions.

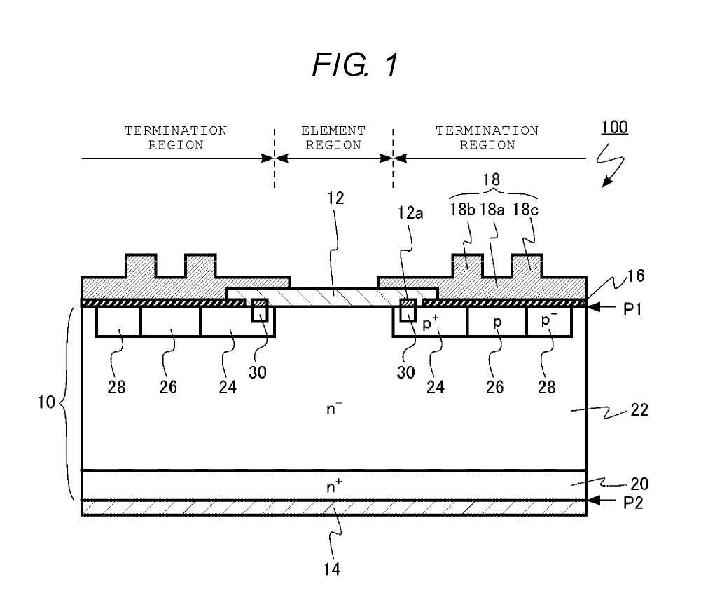

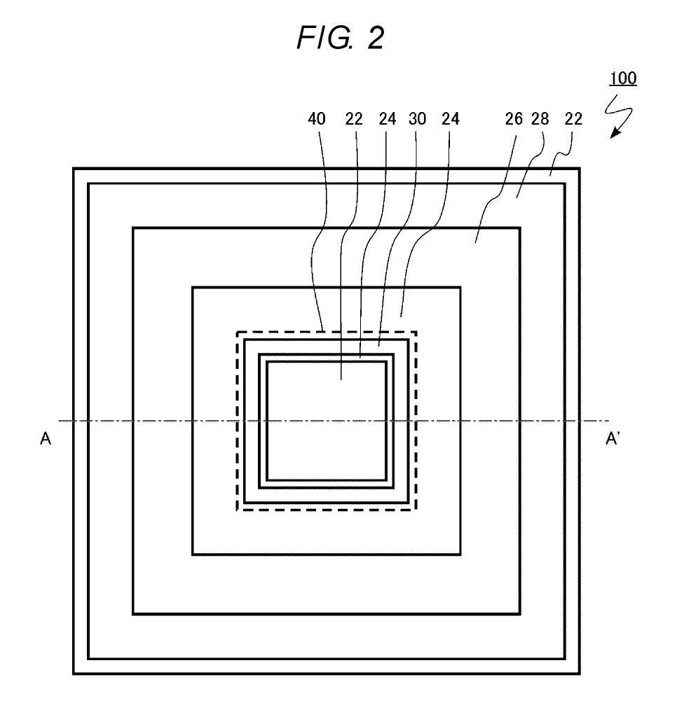

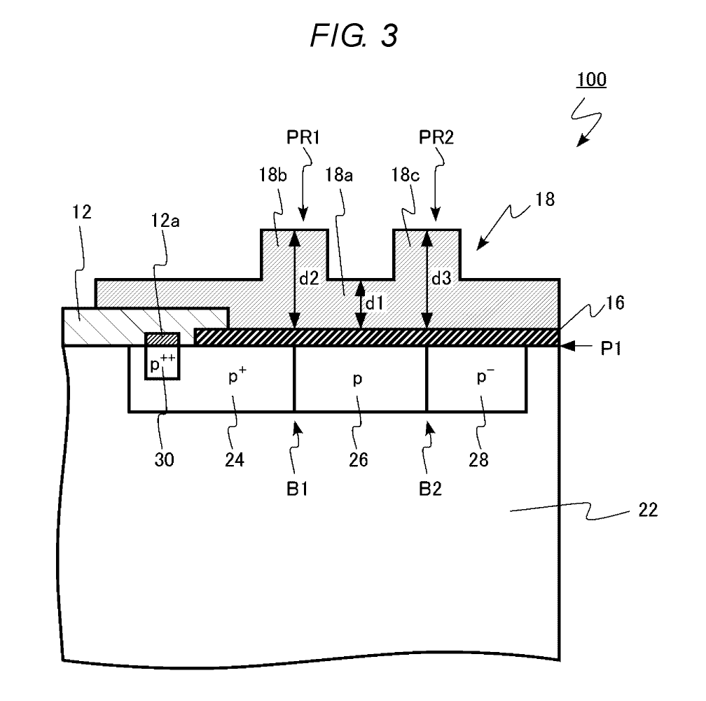

FIG. 1 is a schematic cross-sectional view of the semiconductor device of this embodiment. FIG. 2 is a schematic plan view of the semiconductor device according to this embodiment. FIG. 2 illustrates the pattern of an impurity region on a front surface of the silicon carbide layer. FIG. 1 illustrates a cross-section taken along line A-A′ in FIG. 2. FIG. 3 is a partially enlarged schematic cross-sectional view of the semiconductor device according to this embodiment. The semiconductor device according to this embodiment is a Schottky barrier diode (SBD) 100.

The SBD 100 includes an element region and a termination region surrounding the element region. The element region functions as a region through which current mainly flows during forward biasing of the SBD 100. The termination region is provided with a termination structure. The termination structure reduces the strength of an electric field applied to an end of the element region during reverse biasing of the SBD 100. According to this, a breakdown voltage of an end of the element region is improved, and thus the avalanche breakdown resistance of the SBD 100 is improved.

The SBD 100 includes a silicon carbide layer 10, an anode electrode (first electrode) 12, a cathode electrode (second electrode) 14, a field oxide film (inorganic insulating film) 16, and a polyimide film (resin film) 18. An n⁺-type cathode region 20, an n⁻-type drift region (first silicon carbide region) 22, a p⁺-type edge region (second silicon carbide region) 24, a p-type first resurf region (third silicon carbide region) 26, a p-type second resurf region (fourth silicon carbide region) 28, and a p⁺⁺-type contact region 30 are provided in the silicon carbide layer 10.

The silicon carbide layer 10 includes a first plane and a second plane that is spaced from the first plane. In FIG. 1, the first plane is a plane on an upper side of the drawing, and the second plane is a plane on a lower side. Hereinafter, the first plane is referred to as a front surface, and the second plane is referred to as a rear surface.

For example, the silicon carbide layer 10 is a single crystal SiC having a 4H—SiC crystalline structure. For example, the film thickness of the silicon carbide layer 10 is 5 μm to 600 μm.

The lower surface of the n⁺-type cathode region 20 forms the second plane P2 of the silicon carbide layer 10. The cathode region 20 contains an n-type impurity. Examples of the n-type impurity include nitrogen (N). For example, an impurity concentration of the n-type impurity is 1×10¹⁸ cm⁻³ to 1×10²⁰ cm⁻³.

The n⁻-type drift region (first silicon carbide region) 22 is provided on the cathode region 20. A portion of the drift region 22 forms a portion of the front surface of the element region and thus a portion of the first plane P1. The drift region 22 contains an n-type impurity. Examples of the n-type impurity include nitrogen (N). For example, an impurity concentration of the n-type impurity is 5×10¹⁴ cm⁻³ to 1×10¹⁷ cm⁻³.

A portion of the p⁺-type edge region (second silicon carbide region) 24 provides a portion of the first plane P1 and is located between the first plane P1 and the drift region 22. The edge region 24 extends to the first plane P1. The edge region 24 is located in such a manner that at least a portion thereof surrounds a region 40 (region surrounded by a dotted line in FIG. 2) in which the anode electrode 12 and the surface of the silicon carbide layer 10 are in contact with each other. The edge region 24 surrounds the element region.

The edge region 24 contains a p-type impurity. Examples of the p-type impurity include aluminum (Al). For example, an impurity concentration of the p-type impurity is 5×10¹⁷ cm⁻³ to 5×10¹⁹ cm⁻³.

A portion of the p-type first resurf region (third silicon carbide region) 26 forms a portion of the first plane P1 and thus is located between the first plane P1 and the drift region 22. The first resurf region 26 surrounds the edge region 24, and contacts the edge region 24.

The first resurf region 26 contains a p-type impurity. Examples of the p-type impurity include aluminum (Al). An impurity concentration of the p-type impurity in the first resurf region 26 is lower than an impurity concentration of the p-type impurity in the edge region 24. For example, the impurity concentration of the p-type impurity is 5×10¹⁶ cm⁻³ to 1×10¹⁸ cm⁻³.

A portion of the p⁻-type second resurf region (fourth silicon carbide region) 28 forms a portion of the first plane P1, and it extends between the first plane P1 and the drift region 22. The second resurf region 28 surrounds the first resurf region 26. The second resurf region 28 contacts the first resurf region 26.

The second resurf region 28 contains a p-type impurity. Examples of the p-type impurity include aluminum (Al). An impurity concentration of the p-type impurity in the second resurf region 28 is lower than the impurity concentration of the p-type impurity in the first resurf region 26. For example, the impurity concentration of the p-type impurity is 1×10¹⁶ cm⁻³ to 1×10¹⁸ cm⁻³.

The p⁺⁺-type contact region 30 is provided in the edge region 24. A portion of the contact region 30 forms a portion of the first plane P1, and the contact region 30 extends between the first plane P1 and the edge region 24. The contact region 30 extends inwardly of the surface of the edge region 24 forming a portion of the first plane P1, and is spaced therein from the first resurf region 26, the portion of the drift region between the edge region 24 and the cathode region 20, and the portion of the drift region 22 surrounded by the edge region 24.

The contact region 30 contains a p-type impurity. Examples of the p-type impurity include aluminum (Al). The impurity concentration of the p-type impurity in the contact region 30 is higher than the impurity concentration of the p-type impurity in the edge region 24. For example, the impurity concentration of the p-type impurity is 1×10¹⁹ cm⁻³ to 1×10²¹ cm⁻³.

The field oxide film 16 is located on the first plane P1 of the front surface over a portion of the edge region 24, over the first and second resurf regions 26, 28, and over the portion of the drift region 20 located between the sidewall of the device and the second resurf region 28. A portion of the polyimide film 18 is located on the field oxide film 16.

The field oxide film 16 includes an opening therein exposing the element region in the opening. For example, the field oxide film 16 is a silicon oxide film. For example, the film thickness of the field oxide film 16 is 0.01 μm to 10 μm.

The anode electrode (first electrode) 12 contacts the first plane P1. The anode electrode 12 is in contact with the drift region 22, the edge region 24, and the contact region 30 at the opening in the field oxide film 16/ A portion of the anode electrode 12 overlies the perimeter of the field oxide film 16. The contact between the anode electrode 12 and the drift region 22 is Schottky contact. It is preferable that the contact between the anode electrode 12 and the contact region 30 is an ohmic contact.

The anode electrode 12 is a metal. For example, the anode electrode 12 is a stacked film of titanium (Ti) and aluminum (Al). The portion of the anode electrode 12 in contact with the contact region 30 is configured as a silicide forming silicide region 12a. For example, the silicide region 12a is a nickel silicide.

The polyimide film 18 is provided on the field oxide film 16 and over a peripheral portion of the anode electrode 12. The polyimide film 18 includes an opening therethrough through which the anode electrode 12 is exposed. The edge region 24, the first resurf region 26, and the second resurf region 28 are located between the polyimide film 18 and the drift region 22.

The polyimide film 18 includes a first region 18a, a second region 18b, and a third region 18c. The film thickness (“d2” in FIG. 3) of the second region 18b of the polyimide film 18 is larger than the film thickness (“d1” in FIG. 3) of the first region 18a of the polyimide film 18. In addition, the film thickness (“d3” in FIG. 3) of the third region 18c of the polyimide film 18 is larger than the film thickness (“d1” in FIG. 3) of the first region 18a of the polyimide film 18. The film thickness d2 of the second region 18b and the film thickness d3 of the third region 18c are approximately the same as each other.

As shown in FIG. 3, the thicker second and third regions 18b, 18c of the polyimide film 18 form a first raised portion PR1 and a second raised portion PR2 extending from a front surface of the polyimide film 18. A front surface of the second region 18b is the projecting limit of the first extending portion PR1. A front surface of the third region 18c is the projecting limit of the second convex extending PR2.

The boundary (“B1” in FIG. 3) between the edge region 24 and the first resurf region 26 is located between the second region 18b and the drift region 22. In addition, the boundary (“B2” in FIG. 3) between the first resurf region 26 and the second resurf region 28 is located between the third region 18c and the drift region 22.

The first extending portion PR1 is located immediately over the boundary B1 between the edge region 24 and the first resurf region 26. The second extending portion PR2 is located immediately over the boundary B2 between the first resurf region 26 and the second resurf region 28.

For example, a width of the first extending portion PR1 is 5 μm to 50 μm. For example, a width of the second extending portion PR2 is 5 μm to 50 μm.

For example, the film thickness d2 of the second region 18b is 1.5 times to 3 times the film thickness d1 of the first region 18a. For example, the film thickness d3 of the third region 18c is 1.5 times to 3 times the film thickness d1 of the first region 18a.

For example, the film thickness d1 of the first region 18a is 3 μm to 15 μm. For example, the film thickness d2 of the second region 18b is 7.5 μm to 30 μm. For example, the film thickness d3 of the third region 18c is 7.5 μm to 30 μm.

In addition, the film thickness of the polyimide film 18 and the width of the extending portions can be measured by scanning electron microscope (SEM).

For example, the polyimide film 18, on which the first extending portion PR1 and the second extending portion PR2 exist in the front surface, can be manufactured by the following manufacturing method. For example, a first polyimide film is applied onto the anode electrode 12 and the field oxide film 16. Then, patterning is performed so that the first polyimide film remains only in a region corresponding to the first convex portion PR1 and the second convex portion PR2.

Next, a second polyimide film is applied onto the anode electrode 12, the field oxide film 16, and the first polyimide film that is patterned. Then, an opening is formed on the anode electrode 12 by patterning of the second polyimide film.

The cathode electrode 14 is provided to contact a rear surface of the silicon carbide layer 10, and thus contact the cathode region 20. It is preferable that the contact between the cathode electrode 14 and the cathode region 20 is an ohmic contact.

The cathode electrode 14 contains a metal. For example, the cathode electrode 14 includes a stacked film of nickel silicide and a metal.

Next, description will be given of operation and effect of the SBD 100 according to this embodiment.

In the vertical SBD, when a reverse bias is applied thereto, an electric field becomes concentrated at an end of the element region. When the electric field is concentrated at the end of the element region and avalanche breakdown occurs in the end of the element region, element breakdown is likely to occur, and thus avalanche breakdown resistance deteriorates. For example, in prior devices a p-type resurf region is provided to a termination region at the periphery of the element region so as to mitigate concentration of the electric field to the end of the element region. Due to depletion of the p-type resurf region, an electric field strength that is applied to the end of the element region is mitigated, and thus the avalanche breakdown is less likely to occur at the end of the element region. As a result, the avalanche resistance of the SBD is improved.

Breakdown electric field strength of silicon carbide is approximately ten times as large as the breakdown electric field strength of silicon. According to this, it is possible to further increase the electric field strength that is applied to the semiconductor layer having a termination structure in comparison to silicon. When the electric field strength that is applied to the semiconductor layer increases, the electric field leaked to an outer side of the semiconductor layer also increases.

When packaging a semiconductor device, for example, sealing may be performed with a sealing resin such as an epoxy resin and a silicon resin. For example, the sealing resin is provided over a polyimide film of a semiconductor device. When the electric field strength that leaks to an outer side of the semiconductor layer increases, electric field strength on a front surface of the polyimide film also increases. According to this, insulation breakdown of the sealing resin on the polyimide film, and the like occur, and thus reliability of the semiconductor device deteriorates.

The prior p-type resurf region is provided, for example, as a multi-stage structure including the p⁺-type edge region and the p-type resurf region. Particularly, at a site in which an impurity concentration of the p-type impurity varies, the electric field concentrates, and electric field strength increases. Accordingly, electric field strength that is leaked to an outer side of the semiconductor layer also increases at the site in which the impurity concentration of the p-type impurity changes. As a result, insulation breakdown of the sealing resin is likely to occur immediately over the site in which the impurity concentration of the p-type impurity varies.

In the SBD 100 according to this embodiment, the film thickness of the polyimide film 18 immediately over a portion in which the impurity concentration of the p-type impurity changes is larger than the film thickness over other regions. Specifically, the film thickness of the polyimide film 18 immediately over the boundary B1 between the edge region 24 and the first resurf region 26 is larger. In addition, the film thickness of the polyimide film 18 immediately over the boundary B2 between the first resurf region 26 and the second resurf region 28 is larger. When the film thickness of the polyimide film 18 is larger, it is possible to reduce electric field strength on the front surface of the polyimide film.

When the film thickness of the polyimide film 18 is made locally thicker, the electric field strength on the front surface of the polyimide film 18 is decreased. Accordingly, insulation breakdown of the sealing resin and the like are suppressed, and thus it is possible to achieve an SBD 100 capable of improved reliability.

In this embodiment, the film thickness of the polyimide film 18 is made locally large. Accordingly, internal stress of the polyimide film 18 is reduced in comparison to a case where the entirety of the polyimide film 18 is made thick. Accordingly, reliability failure caused by the internal stress of the polyimide film 18 is suppressed. For example, peeling-off of the polyimide film 18 and the like are suppressed.

In addition, processing of the polyimide film 18 becomes easier in comparison to the case where the entirety of the polyimide film 18 is made thick. For example, forming of an opening through the thinner portion of the polyimide film over the anode electrode 12 is easier. Accordingly, it is possible to reduce the manufacturing cost of the SBD 100.

It is preferable that the film thickness d2 of the second region 18b and the film thickness d3 of the third region 18c are 1.5 times to 3 times as large as the film thickness d1 of the first region 18a. When the film thickness d2 and the film thickness d3 are below the range, there is a concern that an effect of sufficiently reducing the electric field strength may not be obtained. When the film thickness d2 and the film thickness d3 are over the range, there is a concern that processing of the polyimide film 18 to form the extending regions 18b, 18c may be difficult. It is preferable that the film thickness d2 and the film thickness d3 are 2 or more times as large as the film thickness d1 from the viewpoint of obtaining the effect of sufficiently reducing the electric field strength.

It is preferable that the film thickness d2 of the second region 18b and the film thickness d3 of the third region 18c are in a range of 7.5 μm to 30 μm. When the film thickness d2 and the film thickness d3 are below the range, there is a concern that the effect of sufficiently reducing the electric field strength may not be obtained. In addition, when the film thickness d2 and the film thickness d3 are over the range, there is a concern that processing of the polyimide film 18 may be difficult.

As described above, according to this embodiment, the electric field strength on the front surface of the polyimide film 18 is reduced, and thus it is possible to achieve the SBD 100 capable of achieving an improvement in reliability. In addition, it is possible to achieve the SBD 100 capable of achieving reduction in the manufacturing cost.

### Second Embodiment

A semiconductor device according to this embodiment is the same as the first embodiment except that the film thickness of the second region is larger than the film thickness of the third region. Accordingly, description of contents redundant to those in the first embodiment will be omitted.

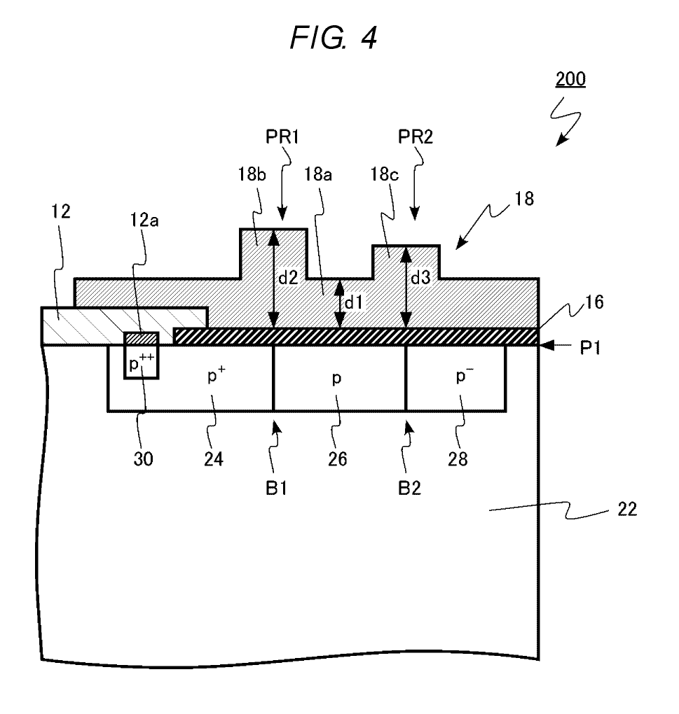

FIG. 4 is a partially enlarged schematic cross-sectional view of the semiconductor device according to this embodiment. The semiconductor device according to this embodiment is a Schottky barrier diode (SBD) 200.

The film thickness (“d2” in FIG. 4) of the second region 18b is larger than the film thickness (“d3” in FIG. 4) of the third region 18c. The film thickness of the polyimide film 18 immediately over the boundary B1 is larger than the film thickness of the polyimide film 18 immediately over the boundary B2.

In this SBD, the electric field strength at the boundary B1 between the edge region 24 and the first resurf region 26 may be higher than electric field strength at the boundary B2 between the first resurf region 26 and the second resurf region 28 in many cases. For example, this is caused by a request on design of the SBD or a variation in an electric field strength distribution due to migration of movable ions during operation of the SBD 200.

In this embodiment, the film thickness d2 of the polyimide film 18 immediately over the boundary B1 is larger than the film thickness d3 of the polyimide film 18 immediately over the boundary B2. Accordingly, it is possible to more effectively reduce electric field strength on the front surface of the polyimide film 18.

According to this embodiment, it is possible to create an SBD 200 capable of achieving an improvement in reliability and a reduction in the manufacturing cost through the same operations as in the first embodiment. In addition, it is possible to effectively improve reliability.

### Third Embodiment

A semiconductor device according to this embodiment is different from the first embodiment in that the semiconductor is a PIN diode including a p-type anode region between the first plane of the silicon carbide layer and the first silicon carbide region. Hereinafter, description of contents redundant to those in the first embodiment will be partially omitted.

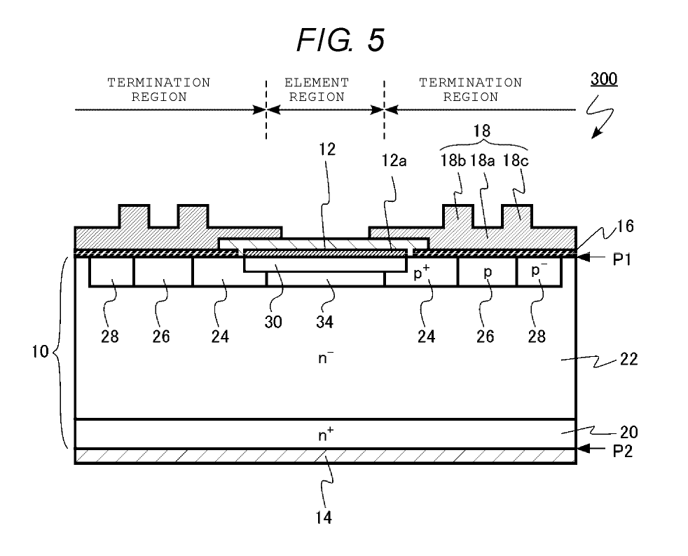

FIG. 5 is a schematic cross-sectional view of the semiconductor device according to this embodiment. The semiconductor device according to this embodiment is a PIN diode 300.

The PIN diode 300 includes a p⁺-type anode region 34. The anode electrode 12 and the anode region 34 are electrically connected. The anode region 34 is connected to the edge region 24.

The anode region 34 contains a p-type impurity. Examples of the p-type impurity include aluminum (Al). For example, an impurity concentration of the p-type impurity is 1×10¹⁸ cm⁻³ to 1×10¹⁹ cm⁻³.

A p⁺⁺-type contact region 30 is provided between the anode electrode 12 and the anode region 34. The anode electrode 12 is in contact with the p⁺⁺-type contact region 30. A silicide region 12a overlies and contacts the p⁺⁺-type contact region 30 and also contacts the anode electrode 12. For example, the silicide region 12a is formed from nickel silicide.

A structure of the termination region is the same as in the first embodiment.

According to this embodiment, it is possible to achieve a PIN diode 300 that is capable of achieving an improvement in reliability and a reduction in the manufacturing cost through the same operations as in the first embodiment.

### Fourth Embodiment

This embodiment is different from the first embodiment in that a semiconductor device of this embodiment is a MOSFET. Hereinafter, description of contents redundant to those in the first embodiment will be partially omitted.

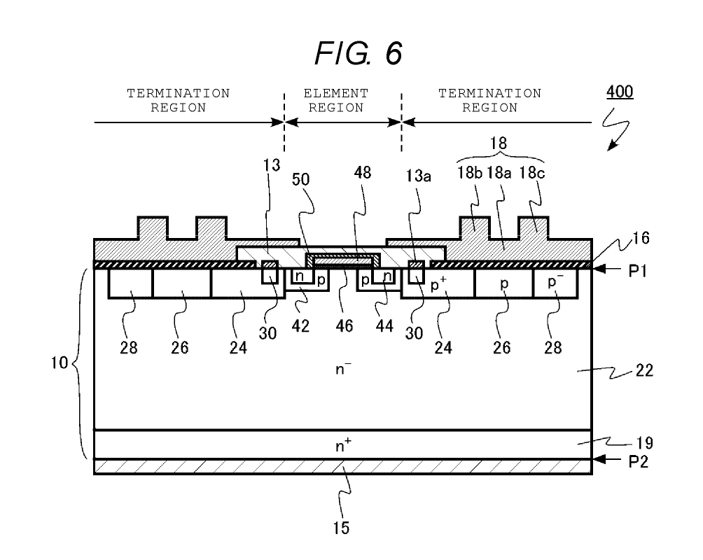

FIG. 6 is a schematic cross-sectional view of the semiconductor device according to this embodiment. The semiconductor device according to this embodiment is a metal semiconductor field effect transistor (MOSFET) 400.

In the MOSFET 400, the element region includes a p-type body region 42, n⁺-type source region 44, a gate insulating film 46, a gate electrode 48, an interlayer film 50, an n⁺-type drain region 19, a source electrode (first electrode) 13, and a drain electrode (second electrode) 15 which are provided in or on surfaces of the silicon carbide layer 10.

The source electrode (first electrode) 13, and the body region 42 and the source region 44 are electrically connected to each other. The source electrode (first electrode) 13 is in contact with the source region 44. The gate electrode 48 and the source electrode 13 are insulated from each other by the interlayer film 50.

A structure of the termination region is the same as in the first embodiment. A silicide region 13a is provided on the portion, of the contact region 30 contacting the source electrode 13. For example, the silicide region 13a is formed from nickel silicide.

According to this embodiment, it is possible to form a MOSFET 400 capable of achieving an improvement in reliability and a reduction in the manufacturing cost through the same operation as in the first embodiment.

In the first to fourth embodiments, description is given of a case where the crystalline structure of silicon carbide is 4H—SiC as an example, but it is also possible to apply the embodiment to a device using SiC having the other crystal structures such as 6H—SiC and 3C—SiC.

In the first to fourth embodiments, description is given of a case where the resurf region is configured as two stages as an example, but the resurf region may be configured as one stage or three or more stages.

In the first to fourth embodiments, description is given of a case where the resin film is a polyimide film as an example, but application of resin films other than the polyimide film is also possible.

In addition, in the embodiments, description is mainly given of the SBD, the PIN diode, and the MOSFET as an example, but it is possible to apply the embodiment to the other devices such as a metal insulator semiconductor field effect transistor (MISFET) and an insulated gate bipolar transistor (IGBT) as long as the transistors are devices including a termination region at the periphery of the element region. In addition, in the embodiments, description is given of a case where the first conductivity type is the n-type, and the second conductivity type is the p-type as an example, but the first conductivity type may be set to the p-type and the second conductivity type may be set to the n-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a silicon carbide layer having a first surface and a second surface, comprising:
a first region of a first conductivity type extending from the first surface to the second surface;
a second region of a second conductivity type extending from the first surface towards the second surface and surrounding a portion of the first region at the first surface; and
a third region of the second conductivity type surrounding the second region, the third region having a second conductivity type impurity concentration lower than a second conductivity type impurity concentration of the second region;
a first electrode extending over the portion of the first region at the first surface and a portion of the second region;
a first insulating layer extending over the third region and partially over the second region; and
a second insulating layer overlying the first insulating layer and having a first portion and a second portion, the second portion being thicker than the first portion and overlying a boundary between the second and third regions.

2. The semiconductor device according to claim 1,
wherein the second portion of the second insulating layer extends away from the silicon carbide layer.

3. The semiconductor device according to claim 1,
wherein the second portion of the second insulating layer has a thickness that is at least 1.5 times as large as a thickness of the first portion of the second insulating layer.

4. The semiconductor device according to claim 1,
wherein the thickness of the second portion of the second insulating layer is 7.5 μm or greater.

5. The semiconductor device according to claim 1, further comprising:
a fourth region of the second conductivity type surrounding the third region, the fourth region having a second conductivity type impurity concentration lower than the second conductivity type impurity concentration of the third region,
wherein the second insulating layer further comprises a third portion thicker than the first portion, the third portion overlying a boundary between the third and fourth regions.

6. The semiconductor device according to claim 5,
wherein the thickness of the second portion is greater than a thickness of the third portion.

7. The semiconductor device according to claim 1, wherein the second insulating layer is a resin.

8. The semiconductor device according to claim 1,
wherein the second insulating layer comprises polyimide.

9. The semiconductor device according to claim 1, further comprising:
a fifth region of the second conductivity type extending into the second region from the first surface, wherein the first electrode contacts the second region on two sides of the fifth region.

10. A semiconductor device, comprising:
a silicon carbide layer having a first surface and a second surface, comprising:
a first region of a first conductivity type extending from a portion of the first surface to the second surface;
a second region of the first conductivity type on the first region;
a third region of a second conductivity type, the third region located between the first region and the second region, a surface of the third region forming a portion of the first surface;
a fourth region of the second conductivity type surrounding the second region and the third region; and
a fifth region of the second conductivity type surrounding the fourth region, wherein the fifth region has a second conductivity type impurity concentration that is less than a second conductivity type impurity concentration of the fourth region;
a first electrode overlying the second region and the third region, the first electrode in contact with the fourth region; and
a first insulating layer overlying the fourth and fifth regions, the first insulating layer having a first portion and a second portion, the second portion being thicker than the first portion and overlying a boundary between the fourth and fifth regions.

11. The semiconductor device according to claim 10, further comprising:
a sixth region of the second conductivity type surrounding the fifth region, wherein a second conductivity type impurity concentration of the sixth region is less than the second conductivity type impurity concentration of the fifth region,
wherein the first insulating layer includes a third portion that is thicker than the first portion and overlying a boundary between the fifth and sixth regions.

12. The semiconductor device according to claim 10, further comprising:
a second electrode contacting the second surface of the silicon carbide layer.

13. The semiconductor device according to claim 10, further comprising:
a second insulating layer between the first insulating layer and the fourth region and between the first insulating layer and the fifth region.

14. The semiconductor device according to claim 10, further comprising an interlayer film in contact with the second region.

15. The semiconductor device according to claim 10, wherein the first insulating layer comprises polyimide.

16. A semiconductor device, comprising:
a silicon carbide layer having a first surface and a second surface, comprising:
a first region of a first conductivity type extending from the second surface to a portion of the first surface;
a second region of a second conductivity type extending from the first surface towards the second surface and surrounding a portion of the first region at the portion of the first surface; and
a third region of the second conductivity type surrounding the second region, the third region having a second conductivity type impurity concentration that is lower than a second conductivity type impurity concentration of the second region;
a first electrode extending over the portion of the first region at the portion of the first surface and a portion of the second region; and
a first insulating layer extending over the third region and partially over the second region and having a first thickness portion and a second thickness portion that is thicker than the first thickness portion, the second thickness portion overlying a boundary between the second and third regions.

17. The semiconductor device according to claim 16,
wherein the second thickness portion of the first insulating layer extends away from the silicon carbide layer.

18. The semiconductor device according to claim 16,
wherein the second thickness portion of the first insulating layer has a thickness that is at least 1.5 times as large as a thickness of the first thickness portion of the first insulating layer.

19. The semiconductor device according to claim 16,
wherein the thickness of the second thickness portion of the first insulating layer is 7.5 μm or greater.

20. The semiconductor device according to claim 16, further comprising:
a fourth region of the second conductivity type surrounding the third region, the fourth region having a second conductivity type impurity concentration that is lower than the second conductivity type impurity concentration of the third region,
wherein the first insulating layer further includes a third thickness portion that is thicker than the first thickness portion, the third thickness portion overlying a boundary between the third and fourth regions.
